(19) United States
(12) Patent Application Publication
(10) Pub. No.: US 2014/0118017 A1
(43) Pub. Date: May 1, 2014

(54) MULTILAYER WIRING BASE PLATE AND PROBE CARD USING THE SAME

(71) Applicant: Kabushiki Kaisha Nihon Micronics, Tokyo (JP)

(72) Inventors: Noboru OTABE, Aomori (JP); Toshinori OMORI, Aomori (JP); Takayasu SUGAI, Aomori (JP)

(21) Appl. No.: 13/943,618

(22) Filed: Jul. 16, 2013

(30) Foreign Application Priority Data
Oct. 30, 2012 (JP) 2012238504

(51) Int. Cl. H05K 1/02

(52) U.S. Cl. CPC H05K 1/0271
USPC 324/756.03; 174/251

(57) ABSTRACT

A multilayer wiring base plate includes an insulating plate including a plurality of synthetic resin layers made of an insulating material, a wiring circuit provided in the insulating plate, a thin-film resistor formed along at least one of the synthetic resin layers to be buried in the synthetic resin layer and inserted in the wiring circuit, and a heat expansion and contraction restricting layer formed to be buried in the synthetic resin layer adjacent to the synthetic resin layer in which the thin-film resistor is formed to be buried, arranged along the thin-film resistor, and having a smaller linear expansion coefficient than a linear expansion coefficient of the adjacent synthetic resin layers.

### RELATED APPLICATION

This application claims the benefit of, and claims priority to, Japanese patent application number 2012-238504, filed on Oct. 30, 2012.

### TECHNICAL FIELD

The subject matter relates to a multilayer wiring base plate in which a thin-film resistor is incorporated and a probe card using the multilayer wiring base plate.

### BACKGROUND

Semiconductor ICs such as semiconductor chips are collectively formed on a semiconductor wafer and undergo an electrical test before being separated into respective chips. For this electrical test, a probe card to be connected to electrode pads of each semiconductor IC as a device under test is used in general. Respective probes of the probe card contact the corresponding electrode pads of the device under test to cause the device under test to be connected to a tester for the electrical test (for example, refer to Patent Literature 1).

In such a probe card, a multilayer wiring base plate is used as a probe base plate, and multiple probes are arranged on one surface of the probe base plate. Also, in a wiring circuit incorporated in this probe base plate or multilayer wiring base plate, an electrical resistor is incorporated for the purpose of electrical matching such as impedance matching or for the purpose of control of supply power to the respective probes (for example, refer to Patent Literature 2).

To incorporate a resistor in such a multilayer wiring base plate, a thin-film resistor is buried and formed in a synthetic resin layer made of an electrical insulating material as a base material for the wiring base plate. This thin-film resistor is made of a metal material having a smaller linear expansion coefficient than a linear expansion coefficient of the aforementioned synthetic resin layer as a base material for the wiring base plate.

Thus, when the aforementioned electrical test of the device under test is performed under heat cycle test conditions, the aforementioned thin-film resistor of the probe card results in receiving relatively large stresses repeatedly at a border with the synthetic resin layer in accordance with a difference in the linear expansion coefficient between the thin-film resistor and the synthetic resin layer to which the thin-film resistor is fixed. Such repeated stresses by the temperature shock promote deterioration of the thin-film resistor and cause breakage.

### Citation List

Patent Literature 1: Japanese Patent Appln. Public Disclosure No. 2010-151497

Patent Literature 2: Japanese Patent Appln. Public Disclosure No. 2008-283131

### SUMMARY

Durability of a thin-film resistor against heat changes of a multilayer wiring base plate in which the thin-film resistor is incorporated is enhanced, and durability of a probe card using this multilayer wiring base plate against heat changes is enhanced.

A multilayer wiring base plate according to an embodiment includes an insulating plate including a plurality of insulating synthetic resin layers, a wiring circuit provided in the insulating plate, a thin-film resistor formed along at least one of the synthetic resin layers to be buried in the synthetic resin layer and inserted in the wiring circuit, and a heat expansion and contraction restricting layer formed to be buried in the synthetic resin layer adjacent to the synthetic resin layer in which the thin-film resistor is formed to be buried, arranged along the thin-film resistor, and having a smaller linear expansion coefficient than a linear expansion coefficient of the adjacent synthetic resin layers.

Also, a probe card according to an embodiment includes a multilayer wiring base plate and a plurality of probes projecting from a surface of the multilayer wiring base plate. The multilayer wiring base plate includes an insulating plate including a plurality of insulating synthetic resin layers, a wiring circuit provided in the insulating plate, a thin-film resistor formed along at least one of the synthetic resin layers to be buried in the synthetic resin layer and inserted in the wiring circuit, and a heat expansion and contraction restricting layer formed to be buried in the synthetic resin layer adjacent to the synthetic resin layer in which the thin-film resistor is formed to be buried, arranged along the thin-film resistor, and having a smaller linear expansion coefficient than a linear expansion coefficient of the adjacent synthetic resin layers. The probes are respectively connected to corresponding wiring paths of the wiring circuit.

In the multilayer wiring base plate according to the embodiment, since the heat expansion and contraction restricting layer arranged in the synthetic resin layer has a smaller linear expansion coefficient than a linear expansion coefficient of the adjacent synthetic resin layers, the heat expansion and contraction restricting layer effectively restricts heat expansion and contraction of the synthetic resin layer along the thin-film resistor in which the thin-film resistor is buried. Consequently, a heat expansion and contraction difference between the thin-film resistor and the synthetic resin layers surrounding the thin-film resistor caused by a heat expansion coefficient difference between them is restricted.

Accordingly, even when the multilayer wiring base plate is used under heat cycle test conditions, for example, which causes an ambient temperature to be changed significantly as in a conventional case, the heat expansion and contraction difference between the thin-film resistor and the synthetic resin layers caused by the heat expansion coefficient difference between them along with these temperature changes is restricted. Thus, a stress acting on the thin-film resistor by this heat expansion and contraction difference is reduced. As a result, durability of the thin-film resistor of the multilayer wiring base plate is enhanced, and durability of the multilayer wiring base plate and the probe card using this the multilayer wiring base plate is improved.

To protect the thin-film resistor from the heat expansion and contraction difference more reliably, the heat expansion and contraction restricting layer is preferably arranged to be approximately parallel to the thin-film resistor and preferably extends outward from an arranging area of the thin-film resistor, going over the arranging area. Since this enables a stress acting on the thin-film resistor on an interface between the thin-film resistor and the synthetic resin layers surrounding the thin-film resistor to be reduced and dispersed more reliably, a protection effect of the thin-film resistor by the heat expansion and contraction restricting layer can be enhanced.

The heat expansion and contraction restricting layer can be made of a metal material. The heat expansion and contraction restricting layer made of the metal material is preferably electrically insulated from the wiring circuit in terms of restriction of noises, restriction of impedance changes, and the like.

The heat expansion and contraction restricting layer can be made of an equal metal material to a metal material constituting the wiring circuit. By doing so, the heat expansion and contraction restricting layer can be formed in a process of forming the wiring circuit without adding a dedicated process for forming the heat expansion and contraction restricting layer.

In relation to both ends of the thin-film resistor, a pair of connection electrodes connected to the wiring circuit can be provided. The connection electrodes as a pair are electrically and mechanically connected to corresponding end portions of the thin-film resistor, respectively. Under a temperature shock such as a heat cycle test, relatively strong stresses are concentrated on connection parts between the thin-film resistor and the connection electrodes as a pair by the heat expansion and contraction difference between the thin-film resistor and the synthetic resin layers surrounding the thin-film resistor. However, by covering the respective corresponding end portions of the thin-film resistor by the connection electrodes as a pair, contact areas of electrical connection portions between the connection electrodes as a pair and the thin-film resistor can be enlarged, and thus the stresses acting on the end portions of the thin-film resistor can be dispersed effectively at the contact areas. Accordingly, the thin-film resistor can be reliably protected from the stresses acting on the thin-film resistor caused by the heat expansion and contraction.

To cover the respective corresponding end portions of the thin-film resistor by the connection electrodes as a pair, step portions respectively receiving the corresponding end portions of the thin-film resistor can be formed on mutually opposed surfaces of the respective connection electrodes. By electrically and mechanically coupling the connection electrodes as a pair with both the corresponding ends of the thin-film resistor by the opposed step portions, the contact areas of the connection portions between the thin-film resistor and the connection electrodes as a pair can be enlarged relatively easily. Thus, with a relatively simple configuration, the thin-film resistor can be more reliably protected from the stresses acting on the thin-film resistor caused by the heat expansion and contraction.

The pair of connection electrodes can be supported by a wiring circuit that is not subjected to significant heat expansion and contraction as in a case of the synthetic resin layer. In this case, the pair of connection electrodes can be supported by a conductive path extending in the synthetic resin layer in a thickness direction of the synthetic resin layer to constitute a part of the wiring circuit. Thus, since the pair of connection electrodes can be coupled with the wiring circuit more reliably than in a case of connecting the pair of connection electrode to a wiring path extending planarly along the synthetic resin layer to support the connection electrodes, the pair of connection electrodes can be supported more tightly.

In a case where the multilayer wiring base plate is formed by repetition of deposition processes of respective materials including the thin-film resistor, the heat expansion and contraction restricting layer made of the metal material can function to smooth a surface of the synthetic resin layer on which a material for the thin-film resistor is deposited.

For example, there is a case in which the heat expansion and contraction restricting layer is formed on a first synthetic resin layer, a second synthetic resin layer is formed on the first synthetic resin layer to bury the heat expansion and contraction restricting layer, the thin-film resistor is formed on the second synthetic resin layer, and a third synthetic resin layer burying the thin-film resistor therein is sequentially deposited on the second synthetic resin layer. In this case, when a via wiring path is formed in a synthetic resin layer to be formed as a lower layer of the first synthetic resin layer, large unevenness may be formed on a surface of the first synthetic resin layer along with formation of the via wiring path.

By depositing a metal material for the heat expansion and contraction restricting layer on the first synthetic resin layer, alleviation of a degree of the unevenness that may be generated on the deposit material can be expected more than in a case of depositing the second synthetic resin layer directly on the first synthetic resin layer. Accordingly, by forming the second synthetic resin layer burying the heat expansion and contraction restricting layer therein on the heat expansion and contraction restricting layer whose unevenness has been alleviated, unevenness on a surface of the second synthetic resin layer is alleviated.

As described above, since the thin-film resistor is formed along the surface of the second synthetic resin layer, an effective length of the thin-film resistor is strongly influenced by unevenness on the surface of the synthetic resin layer. Thus, the more planar the synthetic resin layer surface is, the more the effective length of the thin-film resistor approximates a predetermined value while the larger unevenness of the synthetic resin layer surface is, the larger the effective length of the thin-film resistor gets than the predetermined value. Thus, as described above, by the heat expansion and contraction restricting layer, which restricts and alleviates unevenness on the surface of the synthetic resin layer in which the thin-film resistor is formed, an effect of restricting variation of a resistance value of the thin-film resistor can be expected.

With the embodiment, as described above, since the heat expansion and contraction difference between the synthetic resin layers and the thin-film resistor caused by the heat expansion coefficient difference between them along with changes in an ambient temperature is restricted by the heat expansion and contraction restricting layer, the stress acting on the thin-film resistor by this heat expansion and contraction difference is reduced. Consequently, durability of the thin-film resistor of the multilayer wiring base plate is enhanced, and durability of the multilayer wiring base plate and the probe card using this multilayer wiring base plate is improved.

### BRIEF DESCRIPTION OF THE DRAWINGS

FIG. 1 is a cross-sectional view schematically illustrating a probe card using a prove base plate according to an embodiment.

FIG. 2 is a partially enlarged cross-sectional view of the probe base plate illustrated in FIG. 1.

FIG. 3A illustrates a process for forming a heat expansion and contraction restricting layer on a first synthetic resin layer of the probe base plate illustrated in FIG. 2.

FIG. 3B illustrates a process for forming a thin-film resistor layer on a second synthetic resin layer covering the heat expansion and contraction restricting layer.

FIG. 3C illustrates an etching mask forming process for patterning the thin-film resistor layer.

FIG. 3D illustrates a process for forming a thin-film resistor having a predetermined resistance value from the thin-film resistor layer.

FIG. 3E illustrates a process for forming a third synthetic resin layer burying the thin-film resistor therein.

FIG. 3F illustrates a process for forming a pair of connection electrodes for the thin-film resistor.

FIG. 4A illustrates a process for forming a second heat expansion and contraction restricting layer in a process for manufacturing another probe base plate according to an embodiment.

FIG. 4B illustrates a process for forming a fourth synthetic resin layer covering the second heat expansion and contraction restricting layer.

FIG. 4C illustrates a process for forming a connection pad for a probe.

### DETAILED DESCRIPTION

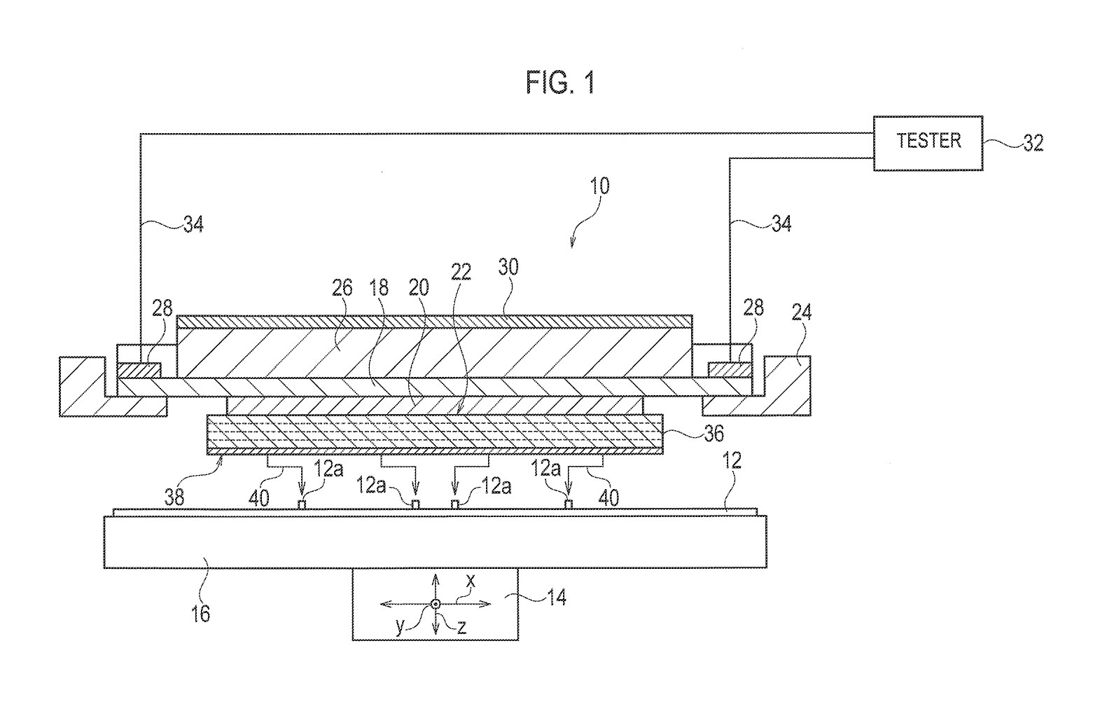

A probe card 10 is used for an electrical test of multiple IC circuits (not illustrated) formed on a semiconductor wafer 12 as illustrated in FIG. 1. On one surface of the semiconductor wafer 12 are formed multiple electrodes 12a for the respective IC circuits. The semiconductor wafer 12 is removably held on a support table 16 as a vacuum chuck held on a support mechanism 14 such as an xyzθ mechanism with the multiple electrodes 12a facing upward.

As is conventionally well known, the vacuum chuck 16 moves along an x axis and a y axis on a horizontal plane (xy plane) perpendicular to a vertical axis (z axis), moves in an up-down direction along the vertical axis, and rotates the horizontal plane (xy plane) around the vertical axis by the xyzθ mechanism 14. By doing so, a position and a posture of the semiconductor wafer 12 against the probe card 10 are controlled.

The probe card 10 includes an entirely circular rigid wiring base plate 18 formed with a glass-containing epoxy resin material as a base material and a probe base plate 22 fixed on a lower surface of the rigid wiring base plate 18 via an electrical connector 20. As for the rigid wiring base plate 18, an edge portion thereof is mounted on an annular card holder 24 provided at a frame of a not-illustrated test head. The electrical connector 20 is an electrical connector having pogo pins, for example. As is conventionally well known, the electrical connector 20 mutually electrically connects wiring paths of a wiring circuit of the rigid wiring base plate 18 to wiring paths of an after-mentioned wiring circuit of the probe base plate 22, which are wiring paths corresponding to the wiring paths of the rigid wiring base plate 18.

In an example illustrated in FIG. 1, an upper surface of the rigid wiring base plate 18 is provided with a reinforcing member 26 for the rigid wiring base plate. Also, to the upper surface of the rigid wiring base plate 18 is attached a cover 30 covering the upper surface of the rigid wiring base plate 18 so as to allow exposure of multiple connectors 28 provided on the upper surface. The respective connectors 28 are connected to the aforementioned corresponding wiring paths of the wiring circuit of the rigid wiring base plate 18. Also, to each connector 28 is removably connected a wiring path 34 extending to a tester 32. Thus, each connector 28 functions as a connection end of the probe card 10 to the tester 32. The reinforcing member 26 and the cover 30 can be dispensed with.

In the example illustrated in FIG. 1, the probe base plate 22 includes a ceramic plate 36 having formed therein wiring paths (not illustrated) corresponding to the respective wiring paths of the wiring circuit of the rigid wiring base plate 18 and fixed on a lower surface of the electrical connector 20 so as for both the corresponding wiring paths to be connected to each other and a multilayer wiring base plate 38 having formed therein a wiring circuit (not illustrated) including wiring paths corresponding to the wiring paths of the ceramic plate and fixed on a lower surface of the ceramic plate 36 so as for the corresponding wiring paths to be mutually connected to the wiring paths of the ceramic plate 36. A lower surface of the multilayer wiring base plate 38 is provided with multiple probes 40 connected to the corresponding wiring paths of the multilayer wiring base plate 38 and connectable to the corresponding electrodes 12a of the semiconductor wafer 12 as is conventionally well known.

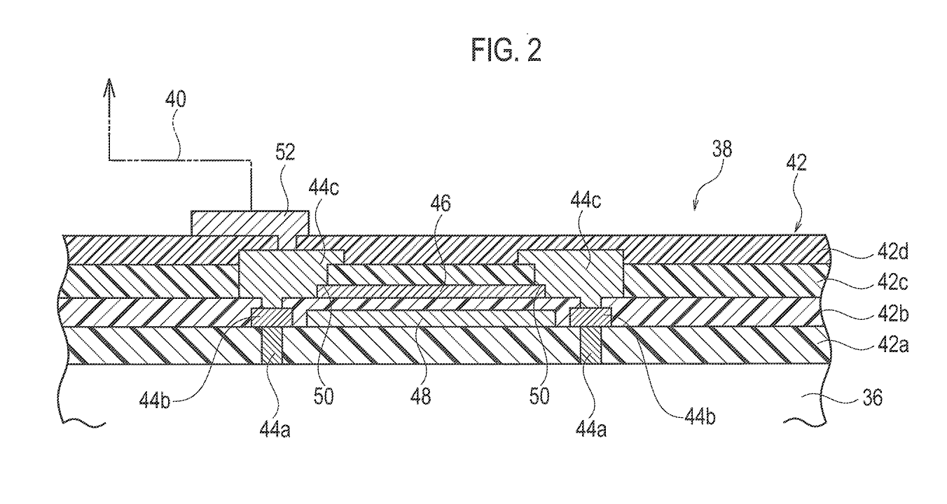

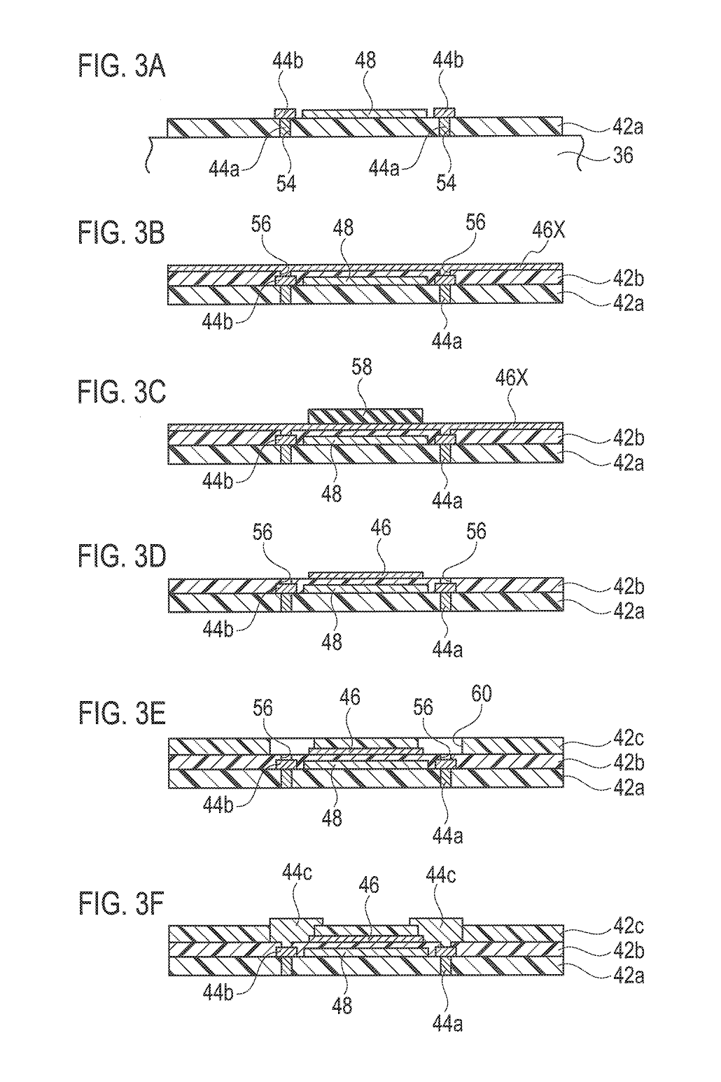

The multilayer wiring base plate 38 is a flexible wiring base plate using a flexible electrical insulating material such as a polyimide synthetic resin material as a base material. FIG. 2 illustrates the multilayer wiring base plate 38 illustrated in FIG. 1 corresponding to FIG. 3A to FIG. 3F illustrating an after-mentioned process for manufacturing the multilayer wiring base plate so that a posture thereof may be illustrated to be upside down.

In an enlarged example illustrated in FIG. 2, the multilayer wiring base plate 38 includes an insulating plate 42 including a four-layer laminated structure from a first layer 42a located on the ceramic plate 36 and located in a lowermost layer as seen in FIG. 2, a second layer 42b, a third layer 42c, and a fourth layer 42d as an uppermost layer. The respective layers 42a to 42d are made of a flexible insulating synthetic resin material consisting primarily of polyimide, for example, and the adjacent layers 42a to 42d are formed to be fixed to one another. Between the respective synthetic resin layers 42a, 42b, 42c and 42d, and on the synthetic resin layer 42d as the uppermost layer are formed wiring paths constituting a wiring circuit of the multilayer wiring base plate 38 as needed, as is conventionally well known.

For achievement of multilayer wiring, the respective synthetic resin layers 42a, 42b, 42c and 42d can have different compositions or can be made of different synthetic resin materials. However, for simplicity of description, an example in which the respective synthetic resin layers 42a, 42b, 42c and 42d are synthetic resin layers having equal compositions will be described as seen in a normal multilayer wiring base plate.

In FIG. 2, as the wiring paths constituting the wiring circuit of the multilayer wiring base plate 38 is formed a pair of via wiring paths 44a passing through the first synthetic resin layer 42a in a direction of a thickness thereof. The respective wiring paths 44a are connected to the corresponding wiring paths of the ceramic plate 36 on one surface of the first synthetic resin layer 42a.

The wiring paths 44a as a pair are connected to corresponding wiring paths 44b formed on the other surface of the first synthetic resin layer 42a. To the via wiring paths 44a as a pair are respectively connected connection electrodes 44c as a pair via the respective wiring paths 44b. Also, the respective wiring paths 44a and 44b are respectively connected to other wiring paths formed between the second to fourth synthetic resin layers 42b to 42d as needed.

Between the connection electrodes 44c as a pair, a thin-film resistor 46 is formed to be buried in the third synthetic resin layer 42c. Also, between the wiring paths 44b as a pair, a heat expansion and contraction restricting layer 48 is arranged to be buried in the second synthetic resin layer 42b.

The thin-film resistor 46 is formed by depositing, e.g., an Ni—Cr alloy material, on the second synthetic resin layer 42b to have a predetermined thickness as described below and thereafter patterning this deposit material in a shape causing a predetermined resistance value to be generated. The thin-film resistor 46 made of the Ni—Cr alloy material has a linear expansion coefficient of approximately 2 to 13 ppm/° C. This thin-film resistor 46 is formed to be fixed on the second synthetic resin layer 42b, and the third synthetic resin layer 42c burying the thin-film resistor 46 therein is formed to be fixed on the thin-film resistor 46. A linear expansion coefficient of these synthetic resin layers 42b and 42c surrounding the thin-film resistor 46 is approximately 40 ppm/° C.

By this linear expansion difference between the thin-film resistor 46 and the synthetic resin layers 42b and 42c surrounding the thin-film resistor, a large stress acts on the thin-film resistor 46 on an interface between the thin-film resistor 46 and the synthetic resin layers 42b and 42c when an ambient temperature of the probe card 10 changes.

To reduce the stress acting on the thin-film resistor 46, the aforementioned heat expansion and contraction restricting layer 48 is provided to be buried in the second synthetic resin layer 42b, which is a lower layer than the third synthetic resin layer 42c.

This heat expansion and contraction restricting layer 48 is made of a material having a smaller value than the linear expansion coefficient of the synthetic resin layers 42b and 42c surrounding the thin-film resistor 46. The heat expansion and contraction restricting layer 48 is made of a metal material constituting wiring paths or a wiring layer formed on the first synthetic resin layer 42a, which is an equal layer to a layer on which the heat expansion and contraction restricting layer 48 is deposited, such as a metal material such as Au, Cu, Ni and Ag.

The heat expansion and contraction restricting layer 48 is arranged along the respective synthetic resin layers 42a, 42b, 42c and 42d so as to be spaced from the thin-film resistor 46 and approximately parallel to the thin-film resistor in the example illustrated in the figure. Also, the heat expansion and contraction restricting layer 48 extends outward from a flat surface area of the thin-film resistor 46, going over both ends of the thin-film resistor 46, as seen on a flat surface parallel to the xy plane in FIG. 1. Since the second synthetic resin layer 42b partially lies between the heat expansion and contraction restricting layer 48 and the thin-film resistor 46, the heat expansion and contraction restricting layer 48 and the thin-film resistor 46 are electrically shielded against each other.

More specifically, the heat expansion and contraction restricting layer 48 is arranged to be buried in the second synthetic resin layer 42b along the thin-film resistor 46 in the vicinity of a portion in which the thin-film resistor 46 is buried and is formed to be fixed to the synthetic resin layers 42a and 42b surrounding the heat expansion and contraction restricting layer 48.

The connection electrodes 44c as a pair formed to be fixed via the respective wiring paths 44b to the wiring paths 44a as a pair have step portions 50 receiving corresponding end portions of the thin-film resistor 46 at inner ends opposed to each other. Since the respective step portions 50 cover the end portions of the thin-film resistor 46 over an entire width of the thin-film resistor at edges of the thin-film resistor 46, the respective step portions 50 contact the thin-film resistor 46 at larger contact areas than in a case of contacting only end surfaces of the thin-film resistor 46 and are thus mechanically and electrically connected to the corresponding end portions of the thin-film resistor 46 reliably.

One connection electrode 44c located on a left side in FIG. 2 is electrically connected to a probe pad 52 arranged on the fourth synthetic resin layer 42d. To this probe pad 52 is fixed the probe 40.

In the probe card 10 according to the embodiment, in a similar manner to that in a conventional case, when the respective probes 40 are connected to the corresponding electrodes 12a of the semiconductor wafer 12 as illustrated in FIG. 1, the respective probes 40 are connected to the tester 32 via the respective corresponding wiring paths of the multilayer wiring base plate 38, the ceramic plate 36, the electrical connector 20, and the rigid wiring base plate 18. Under this connection condition, necessary electrical signals are supplied from the tester 32 via the predetermined probes 40 to respective semiconductor ICs of the semiconductor wafer 12, and response signals are returned from the respective semiconductor ICs via the predetermined probes 40 to the tester 32. By this signal communication, the respective semiconductor IC chips of the semiconductor wafer 12 undergo an electrical test.

In the probe card 10 according to the embodiment, even in a case where this electrical test is performed under heat cycle conditions, and where this causes the multilayer wiring base plate 38 to be subjected to significant ambient temperature changes, heat expansion and contraction of the insulating plate 42 including the synthetic resin layers 42b and 42c surrounding the thin-film resistor 46 are restricted by the heat expansion and contraction restricting layer 48. Thus, since a heat expansion and contraction difference between the thin-film resistor 46 and the synthetic resin layers 42b and 42c surrounding the thin-film resistor 46 is restricted, the stress acting on the thin-film resistor 46 on the interface between the thin-film resistor 46 and the synthetic resin layers 42b and 42c surrounding the thin-film resistor 46 is reduced. Accordingly, breakage of the thin-film resistor 46 caused by rupture and destruction of the thin-film resistor 46 on the interface can be prevented reliably.

Also, stresses act on connection portions between the thin-film resistor 46 and the connection electrodes 44c as a pair as well by a heat expansion and contraction difference between the insulating plate 42 and the thin-film resistor 46 and the pair of connection electrodes 44c buried in the insulating plate. However, since these stresses are dispersed by the large contact areas between the thin-film resistor 46 and the step portions 50 of the respective connection electrodes 44c, it is possible to prevent rupture from being generated at the connection portions between them reliably.

Accordingly, since a stress acting on the thin-film resistor 46 caused by a linear expansion coefficient difference between the insulating plate 42 and the thin-film resistor 46 buried in the insulating plate 42 can be reduced further and can be prevented from concentrating further, and durability of the thin-film resistor 46 can be enhanced further than in a conventional case, deterioration of the thin-film resistor 46 can be prevented, and durability of the probe card 10 can be improved.

Also, as will be described in a process for manufacturing the multilayer wiring base plate 38 described below, since an effect of restricting and alleviating unevenness on a surface of the second synthetic resin layer 42b to be formed by deposition of the thin-film resistor 46 can be expected by the heat expansion and contraction restricting layer 48, an effect of restricting variation of a resistance value of the thin-film resistor 46 can be expected in the heat expansion and contraction restricting layer 48.

Hereinafter, a process for manufacturing the probe card 10 will be described schematically with reference to FIG. 3A to FIG. 3F.

As illustrated in FIG. 3A, a polyimide resin material is coated on a base table such as the aforementioned ceramic plate 36 to form the first synthetic resin layer 42a by thermal cure, and via holes 54 corresponding to the wiring paths of the ceramic plate 36 are formed at predetermined positions of the first synthetic resin layer 42a. Thereafter, a wiring metal material is deposited on the first synthetic resin layer 42a with use of a plating method, for example.

By the plating method, the wiring metal material fills the via holes 54 and is deposited on the first synthetic resin layer 42a with an approximately uniform thickness. Thereafter, by removing an unnecessary deposit material with use of photolithographic and etching techniques, the pair of via wiring paths 44a and the wiring paths 44b on the via wiring paths 44a are formed. Also, between the wiring paths 44b as a pair, the heat expansion and contraction restricting layer 48 spaced from the wiring paths 44b are formed to be fixed on the first synthetic resin layer 42a.

The via wiring paths 44a, the wiring paths 44b, and the heat expansion and contraction restricting layer 48 can be formed by a plating method with use of a predetermined mask in which the wiring metal material is selectively deposited in predetermined portions, instead of the aforementioned method using the etching technique.

As illustrated in FIG. 3B, on the first synthetic resin layer 42a, the second synthetic resin layer 42b is formed to cover the wiring paths 44b and the heat expansion and contraction restricting layer 48, in a similar manner to that of the first synthetic resin layer 42a. This second synthetic resin layer 42b is fixed to the heat expansion and contraction restricting layer 48 and surrounds the heat expansion and contraction restricting layer 48 in cooperation with the first synthetic resin layer 42a as a lower layer. This second synthetic resin layer 42b is provided with openings 56 opened on the wiring paths 44b. After formation of the openings 56, a metal material 46X for the thin-film resistor 46 is deposited on the second synthetic resin layer 42b.

As illustrated in FIG. 3C, with use of a photolithographic technique, an etching mask 58 for the thin-film resistor 46 having a predetermined flat surface shape is formed.

When an unnecessary part of the metal material 46X is removed with use of the etching mask 58, the thin-film resistor 46 having a predetermined resistance value is formed to be fixed on the second synthetic resin layer 42b by the remaining metal material 46X as illustrated in FIG. 3D. At this time, since the metal material 46X deposited in the openings 56 of the second synthetic resin layer 42b is removed as well, the openings 56 are void.

As illustrated in FIG. 3E, on the second synthetic resin layer 42b, the third synthetic resin layer 42c is formed to cover the thin-film resistor 46. In this third synthetic resin layer 42c, recesses 60 for the pair of connection electrodes 44c are formed with use of photolithographic and etching techniques. In the recesses 60, the openings 56 of the second synthetic resin layer 42b are opened. Also, in the recesses 60, the edges of the end portions of the thin-film resistor 46 are exposed over the entire width thereof.

Thereafter, on the third synthetic resin layer 42c, a wiring metal material for the connection electrodes 44c is deposited to fill the openings 56, and by removing an unnecessary part of the wiring metal material on the third synthetic resin layer 42c with use of photolithographic and etching techniques, the pair of connection electrodes 44c coupled with and supported by the via wiring paths 44a via the wiring paths 44b are formed as illustrated in FIG. 3F.

The connection electrodes 44c as a pair can be formed by a plating method with use of a predetermined mask in which the metal material for the pair of connection electrodes 44c is selectively deposited in predetermined portions, instead of the aforementioned method using the etching technique, in a similar manner to that described based on FIG. 3A.

By any of the aforementioned methods, the wiring material deposited in the recesses 60 is deposited along the end portions of the thin-film resistor 46 exposed in the recesses 60. Thus, the connection electrodes 44c as a pair are provided with the step portions 50 contacting and electrically connected to the corresponding end portions of the thin-film resistor 46. Accordingly, the connection electrodes 44c as a pair are reliably connected to the thin-film resistor 46 at the step portions 50 thereof.

The probe 40 can be fixed directly to one connection electrode 44c. However, in the probe card 10, the fourth synthetic resin layer 42d burying the pair of connection electrodes 44c is further deposited, and the probe 40 is fixed to the probe pad 52 on the synthetic resin layer 42d, as illustrated in FIG. 2.

In the aforementioned process for manufacturing the probe card 10, the heat expansion and contraction restricting layer 48 is formed on the first synthetic resin layer 42a by deposition of the metal material as described based on FIG. 3A. However, when via wiring paths are formed under the heat expansion and contraction restricting layer 48 although such a case is not illustrated in the figure, unevenness easily occurs on a surface of the first synthetic resin layer 42a on which the metal material for the heat expansion and contraction restricting layer 48 is to be deposited.

However, in a case where the metal material for the heat expansion and contraction restricting layer 48 is deposited on the first synthetic resin layer 42a, unevenness appearing on a surface of the deposit is physically alleviated further than in a case of forming the second synthetic resin layer 42b directly on this synthetic resin layer 42a. Accordingly, planarity of the deposit surface of the heat expansion and contraction restricting layer 48 is enhanced further than that of the aforementioned uneven surface on the first synthetic resin layer 42a.

Planarity of a surface of the second synthetic resin layer 42b burying the heat expansion and contraction restricting layer 48 whose planarity has been enhanced is enhanced at least in an area in which the heat expansion and contraction restricting layer 48 is arranged. Since the thin-film resistor 46 is formed in the area of the second synthetic resin layer 42b having enhanced planarity by deposition of the metal material, an effective length of the thin-film resistor 46 is not fluctuated significantly by unevenness of the first synthetic resin layer 42a even in a case where the unevenness appears on the surface of the first synthetic resin layer 42a. Accordingly, variation of a resistance value of the thin-film resistor 46 can be restricted.

Although an example in which the single heat expansion and contraction restricting layer 48 is arranged in the insulating plate 42 of the multilayer wiring base plate 38 has been given in the foregoing description, a pair of heat expansion and contraction restricting layers 48 can be arranged on upper and lower sides of the thin-film resistor 46.

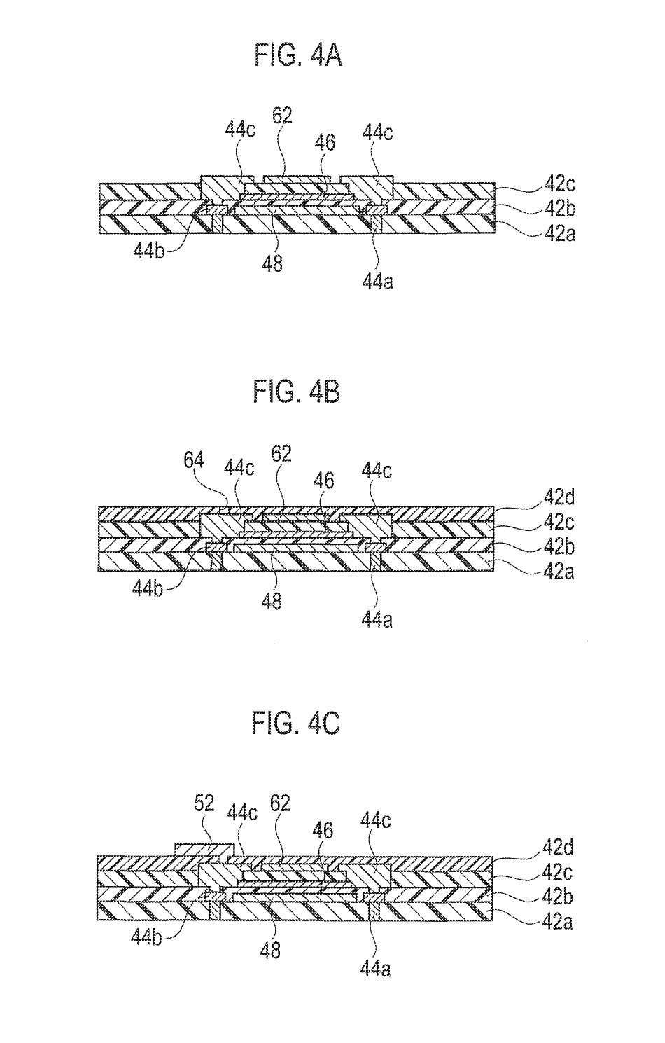

FIG. 4A to FIG. 4C illustrate an example of a process for manufacturing the probe card 10 incorporating a second heat expansion and contraction restricting layer 62 in addition to the heat expansion and contraction restricting layer 48. In FIG. 4A, in the process of forming the pair of connection electrodes 44c described based on FIG. 3F, the second heat expansion and contraction restricting layer 62 is formed to be fixed on the third synthetic resin layer 42c between the connection electrodes 44c as a pair to be mutually spaced from the connection electrodes.

Thereafter, as illustrated in FIG. 4B, the fourth synthetic resin layer 42d is formed on the third synthetic resin layer 42c to bury the second heat expansion and contraction restricting layer 62 and the pair of connection electrodes 44c. This fourth synthetic resin layer 42d is provided with an opening 64 opened to one connection electrode 44c in relation to the connection electrode 44c.

On the fourth synthetic resin layer 42d, the probe pad 52 to be connected to the connection electrode 44c via the opening 64 is formed by deposition of a wiring metal material, and the probe 40 corresponding to the probe pad is fixed although it is not illustrated in the figure, in a similar manner to that in FIG. 2.

The second heat expansion and contraction restricting layer 62 is formed on the third synthetic resin layer 42c, in which the thin-film resistor 42 has been buried, and is buried in the fourth synthetic resin layer 42d contacting the synthetic resin layer 42c. Also, the second heat expansion and contraction restricting layer 62 is electrically insulated from the connection electrodes 44c between the connection electrodes 44c as a pair and extends in parallel with the thin-film resistor 46 to be spaced from the thin-film resistor 46.

The second heat expansion and contraction restricting layer 62 does not extend over an area of the thin-film resistor 46. However, the second heat expansion and contraction restricting layer 62 effectively restricts heat expansion and contraction of the second and third synthetic resin layers 42b and 42c surrounding the thin-film resistor 46 in cooperation with the heat expansion and contraction restricting layer 48 buried in the second synthetic resin layer 42b contacting the third synthetic resin layer 42c burying the thin-film resistor 46 therein. Accordingly, it is possible to effectively prevent the aforementioned deterioration of the thin-film resistor 46 caused by the thermal shock.

The first heat expansion and contraction restricting layer 48 out of the heat expansion and contraction restricting layers 48 and 62 as a pair can be dispensed with, and the aforementioned deterioration of the thin-film resistor 46 caused by the thermal shock can be prevented by the second heat expansion and contraction restricting layer 62.

The heat expansion and contraction restricting layers 48 and 62 can be made of metal materials constituting wiring circuits or nonmetal materials. However, as described above, since using the metal materials constituting wiring circuits enables the heat expansion and contraction restricting layers 48 and 62 to be formed in the processes for forming the wiring circuits, the multilayer wiring base plate 38 and the probe card 10 using the same according to the embodiment can be manufactured without adding dedicated processes for forming the heat expansion and contraction restricting layers.

As the wiring metal materials, various metal materials can be used instead of the aforementioned examples. Also, the thin-film resistor can be made of a metal material such as a Cr—Pd alloy, a Ti—Pd alloy, tantalum oxide, tantalum nitride, Cr, or Ti arbitrarily, instead of the aforementioned Ni—Cr alloy.

The respective synthetic resin layers of the multilayer wiring base plate can be made of various insulating synthetic resin materials instead of the aforementioned polyimide synthetic resin layers or polyimide synthetic films.

The described subject matter is not limited to the above embodiments but may be altered in various ways without departing from the spirit and scope presented here.

For example, as is conventionally well known, the probe card 10 can dispense with the electrical connector 20. In this case, the probe base plate 22 is directly fixed to the rigid wiring base plate 18, and the aforementioned mutually corresponding wiring paths of the rigid wiring base plate 18 and the probe base plate 22 are connected directly.

What is claimed is:

1. A multilayer wiring base plate comprising:
an insulating plate including a plurality of insulating synthetic resin layers;
a wiring circuit provided in the insulating plate;
a thin-film resistor formed along at least one of the synthetic resin layers to be buried in the synthetic resin layer and inserted in the wiring circuit; and
a heat expansion and contraction restricting layer formed to be buried in the synthetic resin layer adjacent to the synthetic resin layer in which the thin-film resistor is formed to be buried, arranged along the thin-film resistor, and having a smaller linear expansion coefficient than a linear expansion coefficient of the adjacent synthetic resin layers.

2. The multilayer wiring base plate according to claim 1, wherein the heat expansion and contraction restricting layer is arranged to be approximately parallel to the thin-film resistor and extends outward from an arranging area of the thin-film resistor, going over the arranging area.

3. The multilayer wiring base plate according to claim 2, wherein the heat expansion and contraction restricting layer is made of a metal material and is electrically insulated from the wiring circuit.

4. The multilayer wiring base plate according to claim 3, wherein the heat expansion and contraction restricting layer is made of an equal metal material to a metal material constituting the wiring circuit.

5. The multilayer wiring base plate according to claim 4, wherein both ends of the thin-film resistor are electrically connected to connection electrodes as a pair connected to the wiring circuit, respectively, and the connection electrodes as a pair cover respective corresponding end portions of the thin-film resistor.

6. The multilayer wiring base plate according to claim 5, wherein the respective connection electrodes have on mutually opposed surfaces thereof step portions respectively receiving the corresponding end portions of the thin-film resistor and are electrically and mechanically coupled with both the corresponding ends of the thin-film resistor by the opposed step portions.

7. The multilayer wiring base plate according to claim 6, wherein the pair of connection electrodes is supported by a conductive path constituting a part of the wiring circuit, and the conductive path extends in the synthetic resin layer in a thickness direction of the synthetic resin layer.

8. A probe card comprising:
the multilayer wiring base plate according to claim 1; and
a plurality of probes projecting from a surface of the multilayer wiring base plate.
